(19) United States
(12) Patent Application Publication
(10) Pub. No.: US 2026/0031774 A1
(43) Pub. Date: Jan. 29, 2026

(54) HETERO-JUNCTION BIPOLAR TRANSISTOR AMPLIFIER CONTROL CIRCUIT

(71) Applicant: MACOM Technology Solutions Holdings, Inc., Lowell, MA (US)

(72) Inventor: Jean-Marc Mourant, Winchester, MA (US)

(21) Appl. No.: 19/243,890

(22) Filed: Jun. 20, 2025

Related U.S. Application Data
(60) Provisional application No. 63/675,439, filed on Jul. 25, 2024.

(51) Int. Cl. H03F 3/217; H03F 3/19; H03G 3/30

(52) U.S. Cl. CPC H03F 3/2176; H03F 3/19; H03G 3/3042; H03F 2200/451

(57) ABSTRACT

A hetero-junction bipolar transistor (HBT) power amplifier is provided. The HBT power amplifier includes a first transistor, a second transistor and a third transistor, the third transistor being configured to drive a base of the second transistor. The first transistor has a base that is configured to receive a current and a collector that is coupled to a base of the third transistor. The second transistor is an output HBT of the HBT power amplifier. The HBT power amplifier further includes a control circuit configured to provide the current to the base of the first transistor. Related methods of operating an HBT power amplifier are also provided.

### CROSS-REFERENCE TO RELATED APPLICATION(S)

This application claims priority under 35 U.S.C. § 119 to U.S. Provisional Application No. 63/675,439, filed on Jul. 25, 2024, the disclosure of which is incorporated by reference herein in its entirety for all purposes.

### TECHNICAL FIELD

The present disclosure relates generally to semiconductor devices and, more particularly, to hetero-junction bipolar transistors (HBTs).

### BACKGROUND

The gain in a radio frequency (RF) receiver and/or an RF transmitter may affect the dynamic range of a system that includes the RF receiver/transmitter. If the gain is too high, then an amplifier may become non-linear. On the other hand, if the gain is too low, then noise may dominate. Sometimes, the system may be in an environment that changes. For example, the gain may decrease when an ambient temperature increases. Moreover, the output power or the receive gain may need to be reduced to avoid interference. Radios may include compensation for such variations.

A common compensation device is the digital step attenuator (DSA). Though it can be linear and accurate, it may have finite (i.e., limited) resolution (e.g., 1 or 0.5 decibels (dB)) and may require multiple control lines. If fine resolution is needed, a voltage variable attenuator (VVA) can be used as a compensation device. A single control line can change the attenuation as finely as needed. VVAs may have poor accuracy, but can be used with a feedback loop (and detector) to set a precise gain, albeit at the expense of a slow response. Using an attenuator, however, is less power efficient since the amplifier DC current is not reduced when the gain and the output power are reduced.

To implement 1-watt (W) drivers from 0.03 to 5 gigahertz (GHz), gallium arsenide (GaAs) HBTs are commonly used. An amplifier bias current and gain can be controlled by controlling a base voltage of each HBT. An HBT is a type of bipolar junction transistor (BJT) that uses different semiconductor materials for its emitter and base regions, thereby creating a heterojunction. HBTs can handle higher-frequency signals than conventional BJTs. For example, HBTs may handle frequencies up to several hundred GHz, and may be used in RF systems and in applications demanding high power efficiency, such as RF power amplifiers.

FIG. 1A is a graph of a gain-control curve depicting gain (in decibels (dB)) as a function of base voltage (in volts (V)) for a conventional HBT amplifier. As shown in FIG. 1A, portions of the curve may be very steep, due to a base-emitter junction being a diode. The vertical axis illustrates the gain in dB, and the horizontal axis illustrates the base voltage in volts (V).

The steepness of the gain-control curve can make it difficult to set a precise gain with a digital-to-analog converter (DAC) of finite resolution. Another possible challenge is variation due to temperature, supply voltage, and/or die processing, also referred to as PVT (process, voltage and/or temperature) variations. It may be difficult to compensate for these variations.

If complementary metal-oxide-semiconductor (CMOS) or bipolar CMOS (Bi-CMOS) technology is available, these drawbacks can be mitigated by adding control amplifiers in feedback and temperature sensors. If the amplifier is a monolithic GaAs HBT die, however, mitigation may be much more difficult, due to an absence of complementary devices to build operational amplifiers. Moreover, adding a CMOS die in the same package is not always possible because of size and cost constraints.

FIG. 1B is a circuit diagram of a conventional bipolar current mirror 100 for an HBT amplifier. The current mirror 100 may comprise first to fourth transistors BIP1-BIP4 and first to fourth resistors R3-R6. An input to the current mirror 100 may be a direct current (DC) electrical current I_{dc}. In some embodiments, the current I_{dc} may be provided by a current source SRC1. The current I_{dc} may have a value of, for example, 1 milliamp (mA). The current I_{dc} may be provided to a base of the fourth transistor BIP4, as the current source SRC1 may be coupled to the base of the fourth transistor BIP4. Moreover, a collector of a first transistor BIP1 may be coupled to the base of the fourth transistor BIP4. A collector of the fourth transistor BIP4 may be coupled to a positive supply voltage Vcc.

The current mirror 100 may have two outputs (which can be combined), which may be provided by respective collectors of the second and third transistors BIP2 and BIP3. The second and third transistors BIP2 and BIP3 may thus be referred to herein as “output transistors.” According to some embodiments, the outputs provided by the collectors of the second and third transistors BIP2 and BIP3 may be 1 mA each. The gain of the current mirror 100 may thus be 2 mA/1 mA=2.

To reduce/eliminate temperature and process variations, the first to third transistors BIP1-BIP3 may be identical. Moreover, respective emitters of the first to third transistors BIP1-BIP3 may be coupled to electrical ground. The second to fourth resistors R4-R6 may also be identical (e.g., may have identical resistance values). The fourth transistor BIP4 may be an amplifier in feedback that drives the bases of the second and third transistors BIP2, BIP3 directly from the positive supply voltage Vcc. As a result, this may remove a common error where the respective base currents of the second and third transistors BIP2, BIP3 may be subtracted from the current I_{dc} (which is an input current of the current mirror 100).

### SUMMARY

An HBT power amplifier, according to some embodiments herein, may include a first transistor, a second transistor, and a third transistor. The third transistor may be configured to drive a base of the second transistor. The first transistor may have a base that is configured to receive a current and a collector that is coupled to a base of the third transistor. The second transistor may be an output HBT of the HBT power amplifier. The HBT power amplifier further includes a control circuit configured to provide the current to the base of the first transistor. The first, second and third transistors and the control circuit may be integrated on a same die.

A gain-control circuit, according to some embodiments herein, may be configured to provide a current to a base of a transistor of a current-mirror circuit. The current may be based on an input control voltage of the gain-control circuit.

A method of operating an HBT power amplifier, according to some embodiments herein, may include varying amplifier gain of the HBT power amplifier by changing a bias current of the HBT power amplifier.

Techniques of the present inventive concept can provide substantial beneficial technical effects. By way of example only and without limitation, embodiments of the present disclosure may provide one or more of the following advantages, among other benefits:
when the gain of the amplifier is reduced, the DC power is reduced, which improves efficiency of the amplifier compared to using only an attenuator;
provides a more linear gain curve than using a simple supply switch;
amplifier bias current can be driven to very low values compatible with battery operation;
reduces gain variation of the amplifier over changes in temperature.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1A is a graph showing a gain-control curve for a conventional HBT amplifier;

FIG. 1B is a circuit diagram of a conventional current mirror for an HBT amplifier;

FIG. 2 is a schematic block diagram of an HBT amplifier, according to one or more embodiments of the present invention;

FIGS. 3-5 are circuit diagrams of example control circuits that can be used as the control circuit of FIG. 2;

FIG. 6 is a graph showing a variable gain curve for an HBT amplifier, according to one or more embodiments of the present invention;

FIG. 7 is a flowchart illustrating operations of an HBT amplifier, according to one or more embodiments of the present invention; and

FIG. 8 is a simplified block diagram depicting a power amplifier circuit including an HBT power amplifier and an attenuator, according to one or more embodiments of the present invention.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in one or more embodiments, may be described herein in the context of HBT RF power amplifiers having improved gain control. For example, some embodiments mitigate problems with conventional gain control by using control circuitry that can be included on the same die as a GaAs HBT. In some embodiments, the HBT RF power amplifiers may be monolithic GaAs HBT amplifiers, where the gain can be changed by changing the bias current of the amplifiers. As used herein, the term “monolithic” refers to a single die that is shared by both control circuitry and amplifier circuitry. Moreover, the term “bias current,” as used herein, may refer to a main/primary (e.g., output) current of the amplifier circuitry.

It is to be appreciated that the inventive concept is not limited to the specific devices, circuits, systems and/or methods illustratively shown and described herein, and moreover is not limited to HBT RF power amplifiers or HBT devices operating at any particular frequencies and/or power. It will also be apparent to those skilled in the art given the teachings herein that numerous modifications to the embodiments shown are contemplated and are within the scope of the inventive concept. That is, no limitations with respect to the embodiments shown and described herein are intended or should be inferred.

If an accurate input current can be provided, a current-mirror circuit can be used to bias an amplifier accurately, independently of temperature and process variations. To vary the amplifier bias, a parameter (e.g., the only parameter) that may need to be varied is the input current to the current-mirror circuit. This can be relatively straightforward when bipolar junction (e.g., PNP) or p-type field-effect transistor (PFET) devices are available, but may be more difficult when only HBT devices and diodes are available. Also, the HBT turn-on voltage may be about 1.2 V, which can limit a circuit to a stack of two devices within a 5 V supply. Moreover, it may be difficult to create an accurate current source attached to a positive rail.

Another challenge is to provide a gain-control range as large as possible, to improve gain-control accuracy. Biasing to zero current may be insufficient. For example, a 20 dB gain amplifier may have −10 dB gain at zero current and a voltage between base and emitter (VBE)=0.6 V. To achieve −20 dB, a control circuit that can bias the HBT base lower (e.g., VBE=0.3 V), without using a negative supply, may be needed.

To mitigate drawbacks with conventional gain control, embodiments herein can change the gain of amplifiers by changing their biasing. In a common conventional implementation, a transconductor is placed at the input. Part of the output current is steered away from the load by a second stage, reducing the gain proportionately. While this conventional approach is simple, it is not very efficient. The current steered away from the load can be wasted. Some embodiments herein, however, can reduce the amplifier bias current, which may also reduce the transconductance and the gain (since transconductance is proportional to collector current). This may be much more efficient and the gain can be reduced past the 0 dB point by reducing the bias voltage further. A trade-off may be the output compression point, which can drop faster than the gain, as the load may be unchanged.

Embodiments of the present invention will now be described in greater detail with reference to the figures.

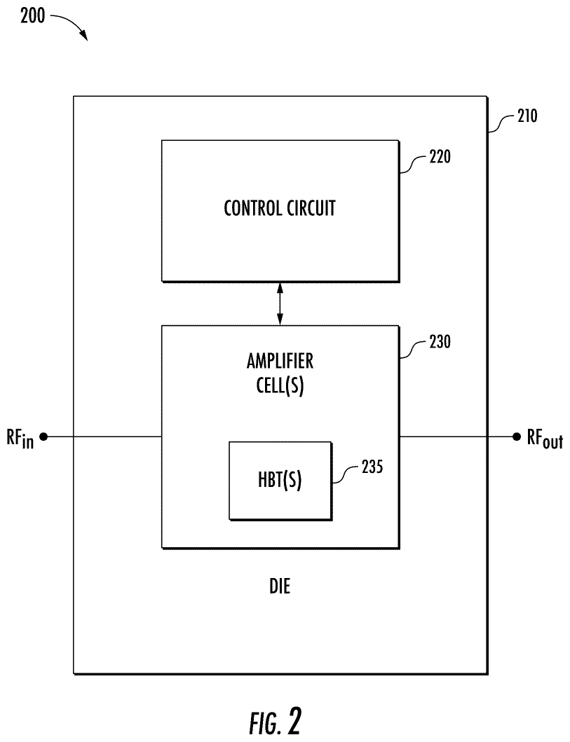

FIG. 2 is a schematic block diagram of an HBT power amplifier 200 according to embodiments of the present invention. The HBT power amplifier 200 includes one or more RF power amplifier cells 230 and a control circuit 220 that is coupled to the amplifier cell(s) 230. The control circuit 220 and the amplifier cell(s) 230 may be on the same semiconductor die 210. The die 210 may comprise, for example, a GaAs substrate, a silicon (Si) substrate, or an indium phosphide (InP) substrate. The die 210 may thus be a GaAs die, an Si die, or an InP die.

Each amplifier cell 230 may comprise an HBT 235 that can amplify an RF signal provided thereto. The die 210 may be referred to herein as an “HBT die” because the die 210 comprises at least one HBT 235. The amplifier cell(s) 230 (and thus the HBT(s) 235) may be coupled between an RF input, RFin, and an RF output, RFout. The HBT(s) 235 can amplify the RF input RFin (e.g., an input RF signal) and can output the amplified RF signal as the RF output RFout. In some embodiments, an input RF impedance matching network may be coupled between the RF input RFin and the amplifier cell(s) 230 and an output RF impedance matching network may be coupled between the amplifier cell(s) 230 and the RF output RFout. For simplicity of illustration, however, the input matching network and the output matching network are omitted from view in FIG. 2.

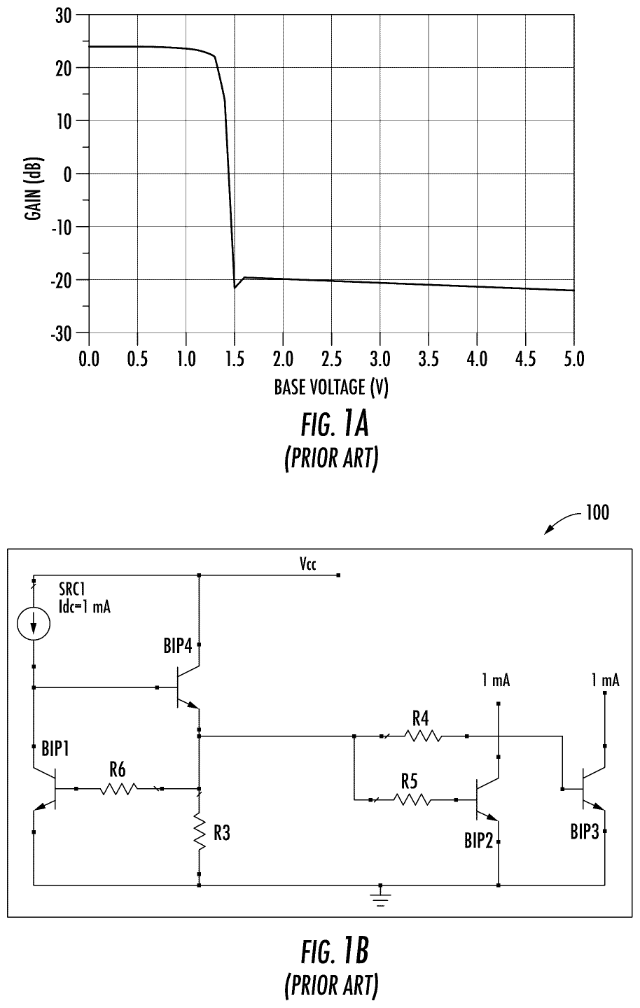

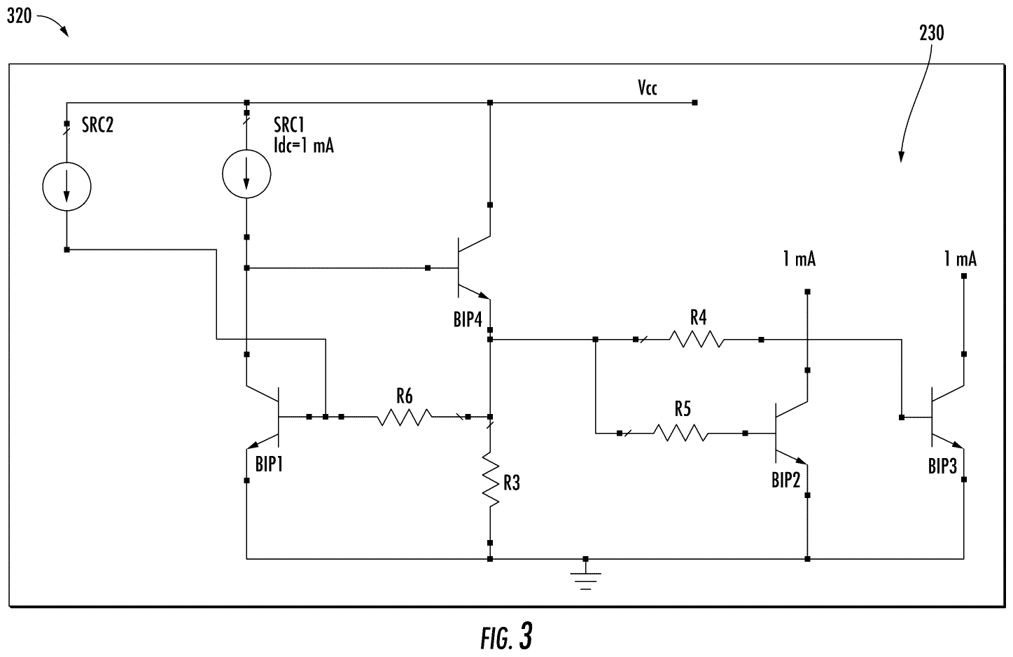

FIG. 3 is a circuit diagram of a control circuit 320 according to embodiments of the present invention. Compared with the conventional current mirror 100 (see FIG. 1B), the control circuit 320 provides an additional (“second”) current source SRC2. The control circuit 320 may include, or may be coupled to, a current-mirror circuit, such as the current mirror 100. The circuit shown in FIG. 3 may thus have two current sources SRC1, SRC2. The second current source SRC2 may be coupled between the positive supply voltage Vcc and the base of the first transistor BIP1. Accordingly, the second current source SRC2 can provide a DC current to the base of the first transistor BIP1.

The second current source SRC2 adds a new current input to the conventional current mirror 100. If this new current input is zero, the bias point may be nominal. As the current increases, some of the current will flow in the base of the first transistor BIP1, which may increase the collector current and pull down the base of the fourth transistor BIP4. This can reduce the base bias of the output transistors BIP2, BIP3 (which may be output HBTs). At one extreme, the VBE bias can be as low as the saturation voltage between collector and emitter (VCEsat) of the first transistor BIP1.

As the second current source SRC2 is a current source rather than a voltage source, a more linear gain control curve may be provided. HBTs may have a linear relationship between base current, I_{B}, and collector current, I_{C} (i.e., I_{C}=β·I_{B}, where β is the DC current gain of the HBT). Moreover, because the emitter of the first transistor BIP1 is grounded, the base of the first transistor BIP1 may be controlled while providing sufficient headroom to add circuitry connected to the positive supply voltage Vcc. In some embodiments, current may be injected (e.g., to implement/facilitate the second current source SRC2) into the control circuit 320 from outside of the control circuit 320 by using a current-output DAC.

According to some embodiments, the output transistors BIP2, BIP3 may be part of the amplifier cell(s) 230 shown in FIG. 2. The output transistors BIP2, BIP3 may thus be HBTs 235 (FIG. 2). Moreover, the amplifier cell(s) 230 may include the resistors R4, R5. In some embodiments, the second source SRC2 (or the second source SRC2 together with the first transistor BIP1 and the fourth resistor R6) may be part of the control circuit 320 and not part of the amplifier cell(s) 230.

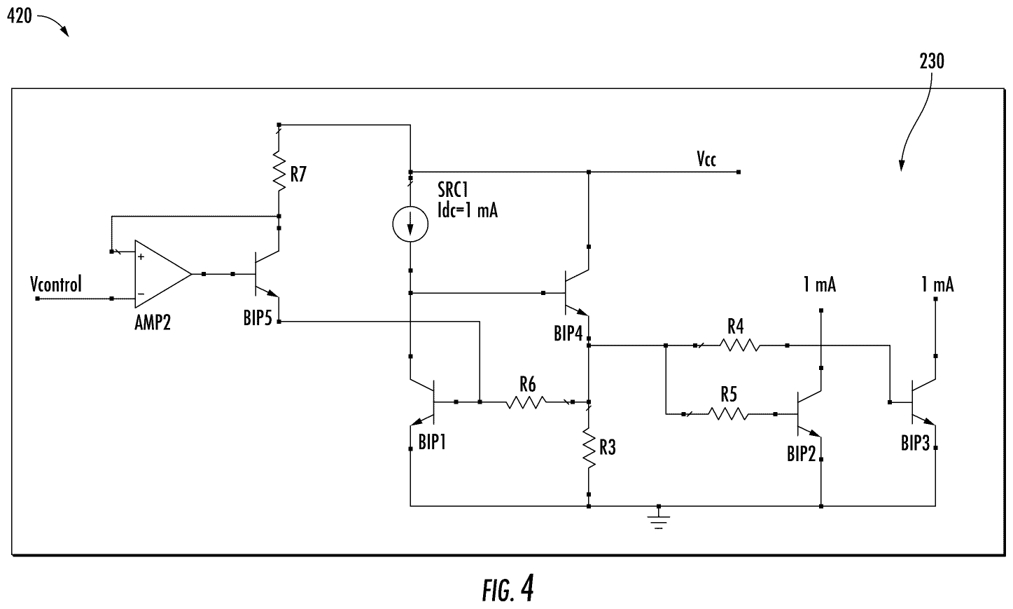

FIG. 4 is a circuit diagram of a control circuit 420 according to embodiments of the present invention. The control circuit 420 includes a voltage drive, which may be required by many applications. In some embodiments, the control circuit 420 comprises, or is coupled to, a current-mirror circuit and has a voltage input that is used to vary an input current of the current-mirror circuit.

For example, the control circuit 420 may include an operational amplifier AMP2. An inverting input (−) of the operational amplifier AMP2 may have an input control voltage Vcontrol coupled thereto. A non-inverting input (+) of the operational amplifier AMP2 may be coupled between a fifth resistor R7 and a fifth transistor BIP5. In some embodiments, an output of the operational amplifier AMP2 may be coupled to a base of the fifth transistor BIP5. Moreover, a collector of the fifth transistor BIP5 may be coupled to the non-inverting input of the operational amplifier AMP2 and an emitter of the fifth transistor BIP5 may be coupled to the base of the first transistor BIP1. Thus, the fifth transistor BIP5 and the operational amplifier AMP2 may be connected in a feedback arrangement. The fifth resistor R7 may be coupled to the positive supply voltage Vcc, and the operational amplifier AMP2, the fifth resistor R7, and the fifth transistor BIP5 may collectively provide an input current to the base of the first transistor BIP1.

The input control voltage Vcontrol is impressed on one side (e.g., the side opposite that of the positive supply voltage Vcc) of the fifth resistor R7. As a result, an input control current based on the control voltage Vcontrol is (Vcc−Vcontrol)/(a resistance of the fifth resistor R7). This control current may be provided to the base of the first transistor BIP1. The control voltage Vcontrol can vary between 2 V and the positive supply voltage Vcc (e.g., 5 V). When the control voltage Vcontrol is equal to Vcc, the current in the fifth resistor R7 may be squeezed to zero and the current-mirror circuit may draw maximum current. When the control voltage Vcontrol is 2 V, the fifth resistor R7 may see the maximum current and the current-mirror circuit can be turned off (as the base of fourth transistor BIP4 may be pulled down by the first transistor BIP1). The amplifier gain may then be at a low (e.g., minimum) level.

Ordinal terms, such as “first,” “second,” “third,” “fourth,” and so on, as used herein, are merely for convenience and can be rephrased/interchanged in various contexts; that is, such ordinal terms are not necessarily intended to convey any particular order, unless the context indicates otherwise. For example, the fourth transistor BIP4 may be referred to herein as a “third” transistor. As another example, the third transistor BIP3 or the fifth transistor BIP5 may be referred to herein as a “fourth” transistor. In a further example, the current source SRC1 may be referred to herein as a “second current source.”

In some embodiments, the operational amplifier AMP2 (or the operational amplifier AMP2 together with the fifth transistor BIP5 and the fifth resistor R7) may be part of the control circuit 420 and not part of the amplifier cell(s) 230 (FIG. 2). The output transistors BIP2, BIP3 (or the output transistors BIP2, BIP3 together with the resistors R4, R5), on the other hand, may be part of the amplifier cell(s) 230.

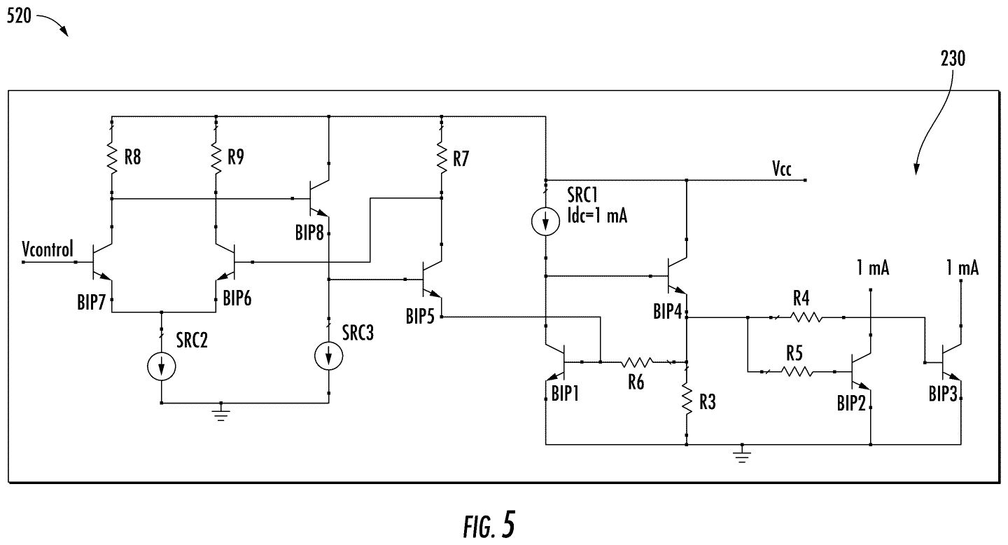

By way of example only and without limitation, FIG. 5 is a circuit diagram of a control circuit 520 according to one or more embodiments of the present invention. The control circuit 520 may include various resistors, transistors, and current sources that are coupled between the control voltage Vcontrol, on one end, and the fifth resistor R7 and the fifth transistor BIP5, on an opposite end. For example, the control voltage Vcontrol may be coupled to a base of a seventh transistor BIP7 (which may also be referred to herein as a “fourth” transistor). A base of a sixth transistor BIP6 may be coupled between the fifth transistor BIP5 and the fifth resistor R7. Collectors of the seventh and sixth transistors BIP7, BIP6 may be coupled to sixth and seventh resistors R8, R9, respectively. A base of an eighth transistor BIP8 may be coupled to the sixth transistor R8. A second current source SRC2 may be coupled between emitters of the sixth and seventh transistors BIP6, BIP7 and electrical ground. A third current source SRC3 may be coupled between an emitter of the eighth transistor BIP8 and electrical ground.

The control circuit 520 is one example implementation of a gain control circuit having a voltage input. In some embodiments, the sixth to eighth transistors BIP6-BIP8, the sixth and seventh resistors R8, R9, and the second and third current sources SRC2, SRC3 may collectively provide the functionality of the operational amplifier AMP2 that is shown in FIG. 4. The operational amplifier AMP2 may thus be implemented using these components of FIG. 5. Moreover, one or more of these resistors, transistors, and/or current sources may be omitted or rearranged in some example implementations.

In some embodiments, the seventh transistor BIP7 (or the seventh transistor BIP7 together with the resistors R7-R9, the transistors BIP5, BIP6, BIP8, and the current sources SRC2, SRC3) may be part of the control circuit 520 and not part of the amplifier cell(s) 230 (FIG. 2). The output transistors BIP2, BIP3 (or the output transistors BIP2, BIP3 together with the resistors R4, R5), on the other hand, may be part of the amplifier cell(s) 230.

The control circuits 320 (FIG. 3), 420 (FIGS. 4), and 520 (FIG. 5) are examples of the control circuit 220 that is shown in FIG. 2. Any of the control circuits 320, 420, and 520 can thus be used to provide gain control for the amplifier cell(s) 230 shown in FIG. 2, and therefore may be referred to herein as “gain-control” circuits.

The transistors BIP that are shown in FIGS. 3-5 may be, for example, HBTs or traditional (i.e., non-HBT) BJTs. The term “transistors BIP,” as used herein, may refer to the four transistors BIP1-BIP4 shown in FIG. 3, the five transistors BIP1-BIP5 shown in FIG. 4, or the eight transistors BIP1-BIP8 shown in FIG. 5. In some embodiments, some (but not all) of the transistors BIP may be HBTs and others of the transistors BIP may be traditional BJTs. For example, referring to FIG. 5, the output transistors BIP2, BIP3 may be HBTs and one or more of the transistors BIP1 and BIP4-BIP8 may be traditional BJTs. In other embodiments, the transistors BIP that are shown in FIGS. 3-5 may all be HBTs or may all be traditional BJTs. Accordingly, the transistors BIP may be any type of BJT.

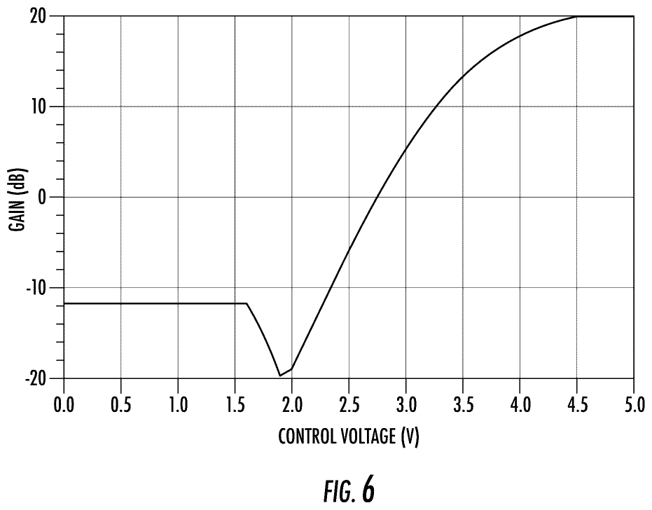

FIG. 6 is a graph showing a variable gain curve for an HBT amplifier according to embodiments of the present invention. The vertical axis illustrates the gain in dB, and the horizontal axis illustrates a control voltage in volts (V). Compared with the curve in FIG. 1A, the curve in FIG. 6 illustrates lower gain for control voltage values between 0 V and about 1.5 V and higher (e.g., monotonically increasing) gain for control voltage values between about 2 V and 5 V. The gain only drops near −20 dB for control voltage values between about 1.75 V and 2 V. In some embodiments, the control voltage shown in FIG. 6 may be the control voltage Vcontrol that is shown in FIGS. 4 and 5, and the curve in FIG. 6 may represent performance of an HBT amplifier 200 (see FIG. 2) that includes the control circuit 420 (see FIG. 4) or the control circuit 520 (see FIG. 5). It may be desirable to operate the HBT amplifier 200 using values of the control voltage Vcontrol that are between about 2 V and 5 V to take advantage of the increasing gain shown in FIG. 6.

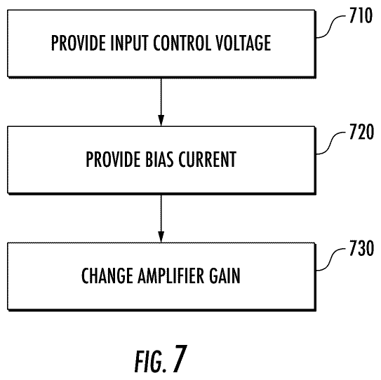

FIG. 7 is a flowchart illustrating operations of an HBT power amplifier 200 (FIG. 2). The operations include providing (Block 710) an input control voltage Vcontrol (FIG. 4) to a control circuit 220 (FIG. 2) of the HBT power amplifier 200. The control circuit 220 may comprise, or be coupled to, a current-mirror circuit. In response to the control voltage Vcontrol, a bias current may be provided (Block 720) to the HBT power amplifier 200. As an example, the bias current may be provided to an HBT 235 (FIG. 2) of the HBT power amplifier 200 based on an output of the control circuit 220 (which output may be based on/controlled by the control voltage Vcontrol). In some embodiments, the bias current may be the output current (e.g., 1 mA each) of the output transistors BIP2, BIP3 (FIG. 3). Gain of the HBT power amplifier 200 may change/vary (Block 730) in response to the bias current (e.g., in response to changing/varying the bias current).

The amplifier bias current and gain can be controlled by controlling a base voltage of the HBT 235. Moreover, the base voltage may be controlled based on the voltage Vcontrol that is input to the control circuit 220. In some embodiments, the voltage Vcontrol may result in a control current that is provided to the control circuit 220. For example, the control current may be provided to the base of a first transistor BIP1 (FIG. 3) of the control circuit 220. An output of the control circuit 220 may be based on the control current.

HBT power amplifiers 200 (FIG. 2) according to some embodiments herein may provide a number of advantages. These advantages may include providing accurate, efficient, continuous gain control for the HBT power amplifiers 200. For example, embodiments herein may provide a monolithic way to control the gain of an HBT power amplifier 200 by changing an input current thereof. This may provide a DAC-friendly high-impedance voltage input and a 20 dB/V gain-control slope. In some embodiments, the HBT power amplifier 200 may include a monolithic die 210 (FIG. 2), such as a monolithic GaAs die, that is shared by both a control circuit 220 (FIG. 2) and one or more HBTs 235 (FIG. 2). According to some embodiments, the control circuit 220 may change its input current based a control voltage Vcontrol (FIG. 4), which may be beneficial for applications that require a voltage drive.

To improve efficiency, many power amplifiers operate in class AB mode. An amplifier operating in class AB mode is generally biased with a small amount of current flowing through the output transistors even when there is no input signal. This ensures that the transistors are always in a state of slight conduction, thereby avoiding a dead zone where both transistors are off and crossover distortion occurs. In some applications, particularly where the RF input signal to the power amplifier is highly compressed (i.e., has a high compression ratio), there may be a loss of gain control in the power amplifier. Specifically, if the power level of the RF input signal is too high, the amplifier may re-bias itself with a high current, with the amplifier effectively operating in class B mode (the “class B effect”). This may lead to a loss of control over the gain and output power of the amplifier; the relationship between the amplifier bias current and gain may become nonlinear.

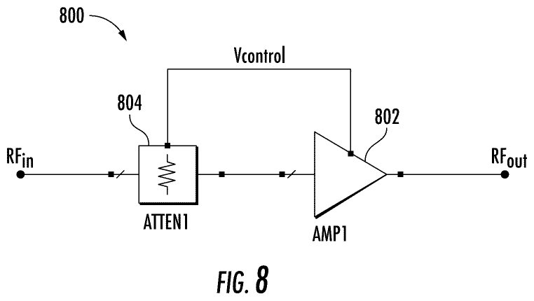

In order to address this issue, an attenuator may be optionally used in front of the power amplifier. By way of example only and without limitation, FIG. 8 is a simplified block diagram depicting an illustrative power amplifier circuit 800, according to one or more embodiments of the inventive concept. Referring to FIG. 8, the power amplifier circuit 800 includes an HBT power amplifier 802, which may be implemented using any of the HBT amplifiers shown in FIGS. 2-5, and a voltage-controlled attenuator (VCA) 804 connected to an input of the HBT power amplifier 802. An RF input signal, RFin, is provided to an input of the VCA 804, an output of the VCA 804 is connected to an input of the HBT power amplifier 802, and an output of the HBT power amplifier 802 provides an RF output signal, RFout, of the power amplifier circuit 800.

The VCA 804 is configured to generate an attenuated version of the RF input signal RFin provided thereto. The amount of attenuation of the RF input signal RFin may be controlled as a function of a control signal, Vcontrol, provided to the VCA 804. In one or more embodiments, for example, the VCA 804 may be configured to attenuate the RF input signal RFin by about 20 dB, although embodiments are not limited thereto. The attenuated RF input signal is provided to the input of the HBT power amplifier 802.

The same control signal Vcontrol provided to the VCA 804 may also be provided to the HBT power amplifier 802 for controlling the gain of the HBT power amplifier 802. Connected in this manner, the attenuation range for the RF input signal is split between the VCA 804 and the HBT power amplifier 802. The HBT power amplifier 802 can still be driven to zero bias, but the zero bias point of the HBT power amplifier 802 will happen more gradually as the input power level provided to the HBT power amplifier 802 is reduced by the VCA 804. The use of the VCA 804 in the power amplifier circuit 800 may improve linearity in the control of the gain of the HBT power amplifier 802.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers, when used, are intended to refer to like elements throughout.

It should also be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present invention.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “main/primary” or “change/vary”) will be understood to be equivalent to the term “and/or.”

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

1. A hetero-junction bipolar transistor (HBT) power amplifier, comprising:
a first transistor, a second transistor and a third transistor, the third transistor is configured to drive a base of the second transistor; and
a control circuit,
wherein the first transistor comprises a base that is configured to receive a current and a collector that is coupled to a base of the third transistor,
wherein the control circuit is configured to provide the current to the base of the first transistor, and
wherein the second transistor is an output HBT of the HBT power amplifier.

2. The HBT power amplifier of claim 1,
wherein the control circuit is configured to receive an input control voltage provided to the control circuit,
wherein the control circuit comprises, or is coupled to, a current-mirror circuit, and
wherein the first transistor, the second transistor, and the third transistor are each part of the current-mirror circuit.

3. The HBT power amplifier of claim 2, wherein the input control voltage is between two volts and a positive supply voltage.

4. The HBT power amplifier of claim 3, wherein a gain of the HBT power amplifier increases as the input control voltage increases between two volts and the positive supply voltage.

5. The HBT power amplifier of claim 2, wherein a collector of the third transistor is coupled to a positive supply voltage.

6. The HBT power amplifier of claim 2, wherein the current is based on the input control voltage.

7. The HBT power amplifier of claim 6, wherein the first transistor further comprises:
an emitter that is coupled to electrical ground.

8. The HBT power amplifier of claim 7,
wherein the control circuit comprises a first current source that is configured to provide the current to the base of the first transistor, and
wherein the current-mirror circuit comprises a second current source that is coupled to the base of the third transistor.

9. The HBT power amplifier of claim 7,
wherein the control circuit comprises an operational amplifier, a resistor, and a fourth transistor that are coupled to each other and collectively configured to provide the current to the base of the first transistor, and
wherein the current-mirror circuit comprises a current source that is coupled to the base of the third transistor.

10. (canceled)

11. The HBT power amplifier of claim 7,
wherein the control circuit comprises first and second current sources, first and second resistors, and fourth and fifth transistors that are collectively configured to provide the current to the base of the first transistor, and
wherein the current-mirror circuit comprises a third current source that is coupled to the base of the third transistor.

12. (canceled)

13. The HBT power amplifier of claim 2, further comprising a voltage-controlled attenuator connected to an input of the HBT power amplifier, the voltage-controlled attenuator is configured to attenuate an input radio frequency (RF) signal provided to the HBT power amplifier as a function of the input control voltage.

14. The HBT power amplifier of claim 1, further comprising a fourth transistor comprising a base,
wherein the third transistor is configured to drive the base of the fourth transistor, and
wherein the fourth transistor is another output HBT of the HBT power amplifier.

15. The HBT power amplifier of claim 1, wherein the HBT power amplifier comprises a monolithic gallium arsenide (GaAs) HBT power amplifier.

16. The HBT power amplifier of claim 1, wherein the control circuit is configured to bias the HBT without using a negative supply voltage.

17. A gain-control circuit, comprising:
a current-mirror circuit including a first transistor, the current-mirror circuit is configured to provide a current to a base of the first transistor,
wherein the current is based on an input control voltage provided to the gain-control circuit, and
wherein a gain of the gain-control circuit is a function of the current.

18. The gain-control circuit of claim 17, further comprising a second transistor that is configured to receive the input control voltage provided to the gain-control circuit.

19. The gain-control circuit of claim 17, further comprising a die that the gain-control circuit shares with a hetero-junction bipolar transistor (HBT) that is configured to amplify radio frequency (RF) power.

20. A method of operating a hetero-junction bipolar transistor (HBT) power amplifier, the method comprising:
varying a gain of the HBT power amplifier by changing a bias current of the HBT power amplifier.

21. The method of claim 20, further comprising providing an input control voltage to a control circuit of the HBT power amplifier,
wherein changing the bias current of the HBT power amplifier is performed in response to varying the input control voltage.

22. The method of claim 21, further comprising attenuating an input radio frequency (RF) signal provided to the HBT power amplifier, a level of attenuation of the input RF signal being a function of the input control voltage.
